(19) United States
(12) Patent Application Publication
(10) Pub. No.: US 2009/0114278 A1
(43) Pub. Date: May 7, 2009

(54) DYE-SENSITIZED SOLAR CELL AND FABRICATION METHOD THEREOF

(76) Inventors: Hyun-Jung LEE, Seoul (KR); Jun-Kyung Kim, Seoul (KR); Eun-Sik Kwak, Gyeonggi-Do (KR); Sang-Soo Lee, Seoul (KR)

Correspondence Address: MCNEELY BODENDORF LLP, P.O. BOX 34175, WASHINGTON, DC, 20043, US

(21) Appl. No.: 12/262,492

(22) Filed: Oct. 31, 2008

(30) Foreign Application Priority Data
Nov. 7, 2007 (KR) 10-2007-0113391.

(51) Int. Cl. H01L 31/00; B05D 5/12

(52) U.S. Cl. 136/256; 427/74

(57) ABSTRACT

A dye-sensitized solar cell and a fabrication method thereof are disclosed. A method for fabricating a dye-sensitized solar cell, includes forming a sacrifice layer comprising colloidal particles on a transparent conductive substrate, supplying a photoelectrode material comprising transition metal oxide nano particles onto the sacrifice layer, thereby filling the transition metal oxide nano particles between the colloidal particles, removing the sacrifice layer by thermal treatment to prepare a photoelectrode having an inverse opal structure, and adsorbing dye molecules onto the photoelectrode.

### CROSS-REFERENCE TO RELATED APPLICATION

This application claims the benefit under 35 U.S.C. §119(a) of a Korean Patent Application No. 10-2007-0113391, filed on Nov. 7, 2007 in the Korean Intellectual Property Office, the entire disclosure of which is hereby incorporated by reference.

### TECHNICAL FIELD

The following description relates to a dye-sensitized solar cell and a fabrication method thereof, and more particularly, to a dye-sensitized solar cell using organic surface-treated transition metal oxide nano particles and a fabrication method thereof.

### BACKGROUND

Generally, a solar cell is a device for converting incident light energy directly into electric energy. A solar cell may produce electricity using sunlight as an unlimited energy source. A representative solar cell is a silicon solar cell. Recently, a dye-sensitized solar cell has been actively studied as a next generation solar cell.

Typically, a silicon solar cell has a structure in which only one portion serves to absorb light to generate an electron-hole pair and to transfer the same. In contrast, a dye-sensitized solar cell has a structure in which dye molecules absorb sunlight to generate an electron-hole pair, and a semiconductor oxide electrode transfers the generated electron. A representative solar cell has been reported by Gratzel et al. in Swiss in 1991 (U.S. Pat. Nos. 4,927,721 and 5,350,644). Since such solar cell has a low fabrication cost per power compared to other existing solar cell, many researchers have paid attention.

Such dye-sensitized solar cell may produce electricity using a photoelectrochemical reaction by light within a visible region. An operation principle thereof is illustrated in FIG. 1. As shown in FIG. 1, dyes 12 adhered to a semiconductor oxide electrode 11 absorbs sunlight to induce an electronic transition from a ground state (D⁺/D) to an excited state (D⁺/D*), thereby generating electron-hole pairs. The excited electrons are impregnated into a conduction band E_{CB} of the semiconductor oxide. The electrons impregnated into the semiconductor oxide electrode 11 are transferred to a transparent conductive substrate 13 through an interface between particles. Such electrons are then moved to a counter electrode 15 coated with a platinum layer 60 through an external circuit 14. An electrolyte containing an oxidation-reduction pair 17 is filled between the semiconductor oxide electrode 11 and the counter electrode 15. The dyes 12 oxidized by the absorption of sunlight receive electrons provided by the oxidation-reduction pair 17 to be thusly reduced again. Here, the oxidation-reduction pair 17 supplying the electrons is reduced again by the electrons moved to the counter electrode 15, thereby completing the process of operating the dye-sensitized solar cell. Also, a load L is connected in series on the transparent conductive substrate 13 and the counter electrode 15, so as to measure short circuit current, open-circuit voltage, filling factor and the like. Accordingly, an efficiency of the cell may be checked.

The dye molecules D/D(+) oxidized by the electronic transition due to the light absorption are reduced again by receiving the electrons provided by the oxidation of iodine ion (3I(−1)/I₃(−1)+2(e−)) within the oxidation-reduction electrolyte. The I₃(−1) ion is then reduced again by the electron (e−) moved to the platinum counter electrode to complete the process of operating the dye-sensitized solar cell. The diffusion of the electrons impregnated into the semiconductor oxide electrode results in a generation of photocurrent. An optical voltage is decided according to the difference between Fermi energy of the semiconductor oxide and the oxidation-reduction potential of the electrolyte.

Here, since an energy conversion efficiency of the solar cell is in proportion to an amount of electrons generated by the light absorption, in order to generate a great amount of electrons, an increase in an amount of the dye molecules adsorbed is required. Therefore, in order to increase the concentration of the adsorbed dye molecules per unit area, transition metal oxide should be fabricated in a nano size to thereafter improve their dispersion, thereby maximizing a specific surface area.

Efforts have been made by research groups to introduce a light amplification effect of a photonic crystal structure to the dye-sensitized solar cell. Most fill titanium precursor (n-butoxide or iso-butyl butoxide) in the photonic crystal structure and thereafter induce a sol-gel reaction, thereby fabricating a titanium oxide inverse opal structure (P. R. Somani, C. Dionigi, M. Murgia, D. Palles, P. Nozar, G. Ruani, Sol. Energy Mater. Sol. Cells, 87, 2005, 513-19).

However, such titanium oxide particles prepared by the sol-gel reaction is difficult to control to have a desired crystal structure (i.e., the inverse opal structure). That is, the titanium oxide particles prepared by a related art has low dispersion, resulting in a structure where titanium oxide particles may not be uniformly dispersed or filled in the photonic crystal structure. Accordingly, a desired titanium oxide inverse opal structure may not be fabricated, resulting in a potential defective light amplification.

### SUMMARY

Accordingly, according to an aspect, there is provided a dye-sensitized solar cell having an enhanced light amplification effect, by preparing transition metal oxide (for example, titanium oxide) nano particles having high dispersion, the particles being organic-surface treated, to infiltrate the same into a three-dimensional (3D) colloidal template fabricated by using various sizes of polymer particles, thereby to fabricate a photoelectrode in a three-dimensional photonic crystal structure, and a fabrication method thereof.

According to another aspect, there is provided a dye-sensitized solar cell having an enhanced long-term stability, by ensuring an efficient path for a infiltration of polymer with a high viscosity or solid electrolyte via ordered bulk-pores.

According to still another aspect, there is provided a dye-sensitized solar cell including, a transparent conductive substrate, a photoelectrode formed with an inverse opal structure on the transparent conductive substrate and comprising organic surface-treated transition metal oxide nano particles, dye molecules adsorbed on the photoelectrode, a counter electrode disposed to face the transparent conductive substrate, and an electrolyte filled between the transparent conductive substrate and the counter electrode.

Each surface of the transition metal oxide nano particles may be coated with a hydrophobic organic material. The hydrophobic organic material may be ketone or alcohol-based compound.

A coating layer comprising the hydrophobic organic material may have an average thickness of 0.1 nm to 20 nm.

The transition metal oxide nano particles may include at least one of titanium dioxide nano particles, zinc oxide nano particles, tin-dioxide nano particles, and at least some of the titanium dioxide nano particles may have an anatase crystallinity.

The transition metal oxide nano particles may have an average diameter of 1 nm to 100 nm.

The photoelectrode may be porous and have two or three dimensional ordered crystal structure.

The photoelectrode may have a plurality of pores, the pores having an average diameter of 100 nm to 10 μm.

The dye-sensitized solar cell may further comprise a blocking layer disposed between the transparent conductive substrate and the photoelectrode.

According to yet another aspect, there is provided a method for fabricating a dye-sensitized solar cell including, forming a sacrifice layer comprising colloidal particles on a transparent conductive substrate, supplying a photoelectrode material comprising transition metal oxide nano particles onto the sacrifice layer, thereby filling the transition metal oxide nano particles between the colloidal particles, removing the sacrifice layer by thermal treatment to prepare a photoelectrode having an inverse opal structure, and adsorbing dye molecules onto the photoelectrode.

The colloidal particles may have an average diameter of 100 nm to 10 μm.

The colloidal particles may be either organic polymer particles or inorganic particles. The organic polymer particles may contain at least one of polystyrene (PS) and polymethylmethacrylate (PMMA). The inorganic particles may contain silica.

The photoelectrode material may be prepared by dispersing the transition metal oxide nano particles in water or alcohol, and the transition metal oxide nano particles may be uniformly filled between the colloidal particles by capillary phenomenon with the water or the alcohol being evaporated.

Each surface of the transition metal oxide nano particles may be coated with a hydrophobic organic material.

The thermal treatment may be performed at least one time at 400° C. to 550° C. for 10 minutes to 2 hours.

The method for fabricating a dye-sensitized solar cell may further comprise pressing the sacrifice layer by using a substrate coated with a fluoric polymer after the transition metal oxide nano particles are filled between the colloidal particles.

A series of steps comprising the step of forming the sacrifice layer, the step of filling the transition metal oxide nano particles between the colloidal particles, and the step of removing the sacrifice layer by thermal treatment may be repeated at least one time or more.

The method for fabricating a dye-sensitized solar cell may further comprise forming a blocking layer between the transparent conductive substrate and the photoelectrode before forming the sacrifice layer.

Other features will become apparent to those skilled in the art from the following detailed description, which, taken in conjunction with the attached drawings, discloses exemplary embodiments of the invention.

### BRIEF DESCRIPTION OF THE DRAWINGS

FIG. 1 is a diagram illustrating a construction of a dye-sensitized solar cell.

FIG. 2 is a diagram illustrating a dye-sensitized solar cell having a photoelectrode(s) with an inverse opal structure according to an exemplary embodiment.

FIGS. 3A to 3E are diagrams illustrating a method for fabricating a photoelectrode with an inverse opal structure according to an exemplary embodiment.

FIG. 4 is a transmission electron microscopic photograph of an organic surface-treated titanium oxide particle.

FIG. 5 is a photograph of an n-butanol solution containing an organic surface-treated titanium oxide particle.

FIG. 6 is a scanning electron microscopic photograph of a surface of a titanium oxide electrode with an inverse opal structure according to an exemplary embodiment.

FIG. 7 is a graph illustrating photocurrent-voltage characteristics of a dye-sensitized solar cell using a titanium oxide electrode with an inverse opal structure fabricated according to an exemplary embodiment.

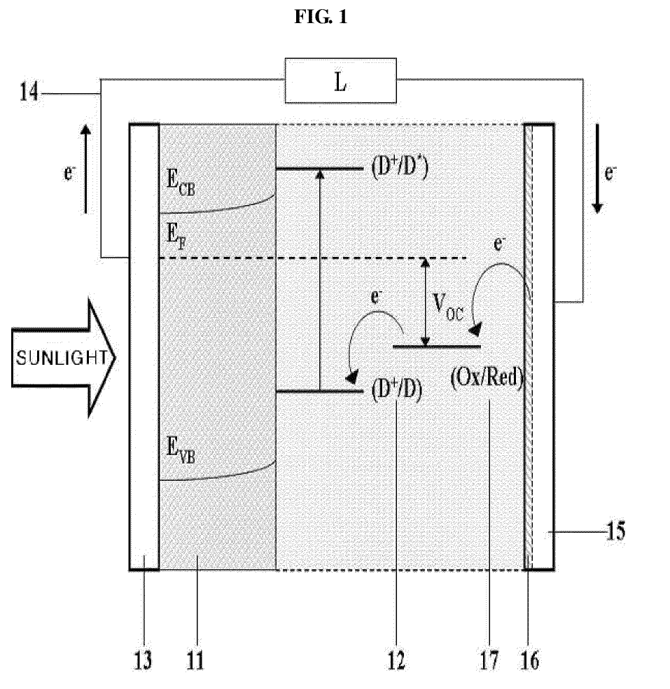

Throughout the drawings and the detailed description, unless otherwise described, the same drawing reference numerals will be understood to refer to the same elements, features, and structures. The elements may be exaggerated for clarity and convenience.

### DETAILED DESCRIPTION

The following detailed description is provided to assist the reader in gaining a comprehensive understanding of the methods, apparatuses and/or systems described herein. Accordingly, various changes, modifications, and equivalents of the systems, apparatuses and/or methods described herein will be suggested to those of ordinary skill in the art. Also, descriptions of well-known functions and constructions are omitted to increase clarity and conciseness.

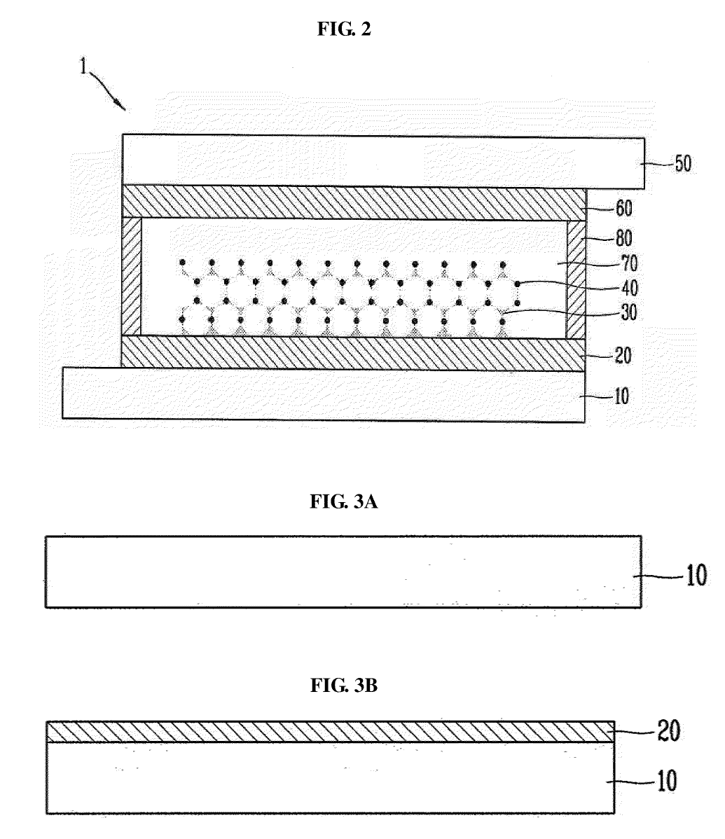

FIG. 2 shows a dye-sensitized solar cell 1 according to an exemplary embodiment. As shown in FIG. 2, the dye-sensitized solar cell 1 comprises a transparent conductive substrate 10, a blocking layer 20 formed on the transparent conductive substrate 10, a photoelectrode(s) 30 formed on the blocking layer 20, dye molecules 40 adsorbed on the photoelectrode 30, a counter electrode 50 arranged to face the transparent conductive substrate 10, a platinum layer 60 formed on one surface of the counter electrode 50 facing the transparent conductive substrate 10, an electrolyte 70 filled between the transparent conductive substrate 10 and the counter electrode 50, and a sealing portion 80 formed along an edge between the transparent conductive substrate 10 and the counter electrode 50.

According to further exemplary embodiments, the blocking layer 20 may be omitted, and the platinum layer 60 may be omitted or replaced by carbon nanotube layer and the like.

The transparent conductive substrate 10 may have a structure in which a transparent electrode having a conductivity is formed on a transparent substrate. A glass substrate and a flexible polymer substrate may be used as the transparent substrate. Material to be used for the polymer substrate may include polyethylenephthalate (PET), polyethylenenaphthalate (PEN), polycarbonate (PC) and the like. The transparent electrode may include indium tin oxide (ITO), fluorine tin oxide (FTO) or the like. The transparent conductive substrate 10 is employed such that sunlight may be transmitted therethrough to be internally incident. Also, the word ‘transparent’ used herein may refer to a material having a high optical transmittance as well as a material with 100% of optical transmittance.

The blocking layer 20 may be formed on the transparent conductive substrate 10. The blocking layer 20 may be made of oxide. The blocking layer 20 may serve to reinforce an adhesiveness between the transparent conductive substrate 10 and the photoelectrode 30.

The photoelectrode 30 may be formed on the blocking layer 20, or the transparent conductive substrate 10 where the blocking layer 20 is omitted. Dye molecules 40 are adsorbed onto the photoelectrode 30. The photoelectrode 30 comprises transition metal nano particles. As shown in FIG. 2, the photoelectrode 30 is overall prepared in an inverse opal structure. That is, the photoelectrode 30 is prepared to be porous. The inverse opal structure of the photoelectrode 30 allows a three-dimensional photonic crystal to be implemented, thereby enabling an expectation of a light amplification effect. In detail, the inverse opal structure with ordered porosities allows an effective electron transport path, thus to enhance a photoelectric conversion efficiency of the dye-sensitized solar cell 1. Also, ordered bulk-pores in the inverse opal structure provides a path efficient for an infiltration of polymer with a high viscosity or solid electrolyte, thereby enhancing a long-term stability of the dye-sensitized solar cell 1. In an exemplary embodiment, pores in the inverse opal structure have an average diameter in the range of about 100 nm to 10 μm.

It may be desirable to have the transition metal oxide nano particles in the inverse opal structure with a size as small as possible. That is, the smaller size of the transition metal oxide nano particles increases a surface area, resulting in allowing more dye molecules 40 to be adsorbed onto the nano particles. In case of such increased adsorption of dye molecules 40, more electrons are produced, thus improving an energy conversion efficiency of the dye-sensitized solar cell 1. However, where the transition metal oxide nano particles are very small in size, an adhesiveness between the transition metal oxide nano particles and the blocking layer 20 may be decreased during a thermal treatment or the like, causing a probability of exfoliation. Hence, according to an exemplary embodiment, the transition metal oxide nano particles has an average diameter in the range of 1 nm to 100 nm. The transition metal oxide nano particles according to an exemplary embodiment may be one of titanium dioxide (TiO₂) nano particles, zinc oxide (ZnO) nano particles, tin-dioxide (SnO₂) nano particles, or complex thereof. It is understood that types of nano particles is not limited thereto, and other types of transition metal oxide nano particles may be employed. In the exemplary embodiment, titanium dioxide nano particles were used to fabricate the dye-sensitized solar cell. Here, titanium dioxide nano particles having an anatase crystallinity with an electron transport capability may be selected for use.

According to an aspect, each surface of the exemplary transition metal oxide nano particles is treated by using an organic material. In detail, each surface of the transition metal oxide nano particles is coated with a hydrophobic organic material. Such hydrophobic material may include, for example, ketone containing atomic oxygen or alcohol-based compound; however, it is not limited thereto. In an exemplary embodiment, acetylacetone is used as the hydrophobic organic material. A coating layer comprising the hydrophobic organic material may have a thickness of about 0.1 nm to 20 nm. Accordingly, dispersion of the transition metal oxide nano particles to an alcohol-based organic solvent is improved due to the surface-coated hydrophobic organic material.

The dye molecule 40 adsorbed on the surface of the nano particles contained in the photoelectrode 30 may be one of a ruthenium-based dye module and a coumarin-based dye molecule. Where light is incident on such type of dye molecules 40, electrons are produced. The produced electrons are transferred to the transparent conductive substrate 10 via the photoelectrode 30 defining a path.

The counter electrode 50 is disposed to face the transparent conductive substrate 10. The counter electrode 50 may have, similar to the transparent conductive substrate 10, a structure in which a transparent electrode having a conductivity is formed on a substrate. The substrate may be a glass substrate or a transparent polymer substrate consisting of any one of PET, PEN, PC, PP and PI. The transparent electrode may include indium tin oxide (ITO), fluorine tin oxide (FTO).

The platinum layer 60 is disposed on one surface of the counter electrode 50 facing the transparent conductive substrate 10. The efficiency of the platinum layer 60 may depend on reflectivity. Accordingly, it is desirable to select a material having high reflectivity for the platinum layer 60. Instead of the platinum layer, a carbon nanotube layer may be used. Alternatively, the platinum layer 60 may be omitted where the counter electrode 50 itself has an efficient conductivity.

The electrolyte 70 is formed between the photoelectrode 30 and the platinum layer 60. The electrolyte 70 may contain iodine, and serves to receive electrons from the counter electrode 50 by oxidation and reduction, and to transfer the received electrons to the dye molecules 40 having lost electrons. Such electrolyte is substantially uniformly dispersed in pores of the photoelectrode 30.

The sealing portion 80 is formed along an edge of the transparent conductive substrate 10 and the counter electrode 50. The sealing portion 80 may contain a thermoplastic polymer material, and be hardened by heat or ultraviolet. As an example, the sealing portion 80 may contain an epoxy resin.

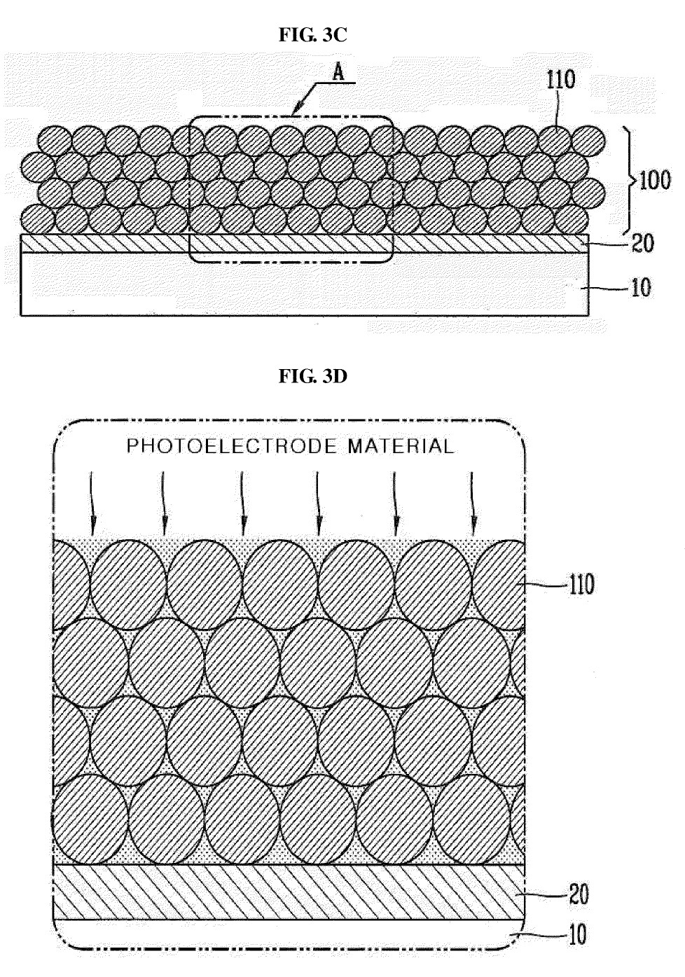

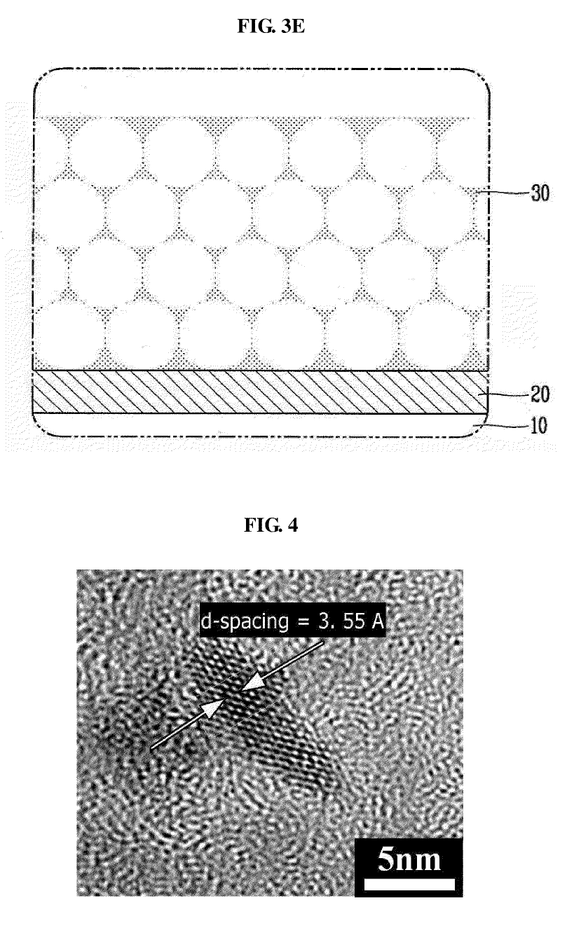

Hereinafter, an exemplary fabrication method of a dye-sensitized solar cell having the aforesaid structure will be described with reference to FIGS. 3A to 3E.

As shown in FIG. 3A, a transparent electrode is deposited on a glass substrate or a polymer substrate, thereby preparing a transparent conductive substrate 10. Here, material to make the polymer substrate may include, for example, polyethylenephthalate (PET), polyethylenenaphthalate (PEN), polycarbonate (PC) and the like. The transparent electrode formed on the substrate may be fabricated by using indium tin oxide (ITO), fluorine tin oxide (FTO) or the like.

As shown in FIG. 3B, a blocking layer 20 is formed on the transparent conductive substrate 10. The blocking layer 20 may be defined by coating a certain thickness of oxide on the transparent conductive substrate 10. In detail, a mixture of 7.5 wt % Ti (IV) bis(etyleacetoacetonato)-di isopropoxide/butanol solution is uniformly deposited on the transparent conductive substrate 10 in a spin coating manner, and then thermally treated two consecutive times at 150° C. for 30 minutes and at 500° C. for 15 minutes, thereby preparing the blocking layer 20. The material of the blocking layer 20 may not be limited to the aforesaid materials, and also the number of thermal treatment, conditions and the like may not be limited thereto, but rather, variously modification within the scope and spirit of the instant teaching may be made. The blocking layer 20 may function to enhance an adhesiveness between the transparent conductive substrate 10 and the photoelectrode 30. The blocking layer 20 may be fabricated in a manner of one of a deposition, an electroanalysis and a wet process.

As shown in FIG. 3C, a sacrifice layer 100 is formed by depositing a colloidal solution on the blocking layer 20 by a certain thickness. The colloidal solution may contain 0.1 wt % to 5 wt % (preferably, approximately 2.5 wt %) of colloidal particles 110 with a diameter of 100 nm to 10 μm in a solvent, such as water or alcohol. The colloidal particles 110 may be polystyrene colloidal particles. The thickness of the sacrifice layer 100 may depend on the size of the dye-sensitized solar cell desired to be fabricated, but it may preferably be fabricated with a thickness of about 10 μm to 20 μm. In an exemplary embodiment, the sacrifice layer 100 is fabricated with thickness of 12 μm and 23 μm. The thusly-formed sacrifice layer 100 may have a porous structure due to the colloidal particles, and construct a colloidal self-assembling photonic crystal. Here, the term ‘sacrifice layer’ is used because such layer is removed during a thermal treatment process.

As shown in FIG. 3D, a prepared photoelectrode material (e.g., a butanol solution having titanium oxide nano particles dispersed therein) is slowly supplied onto the sacrifice layer 100. Here, FIG. 3D is an enlarged view of part ‘A’ of FIG. 3C. The photoelectrode material includes transition metal oxide nano particles. Accordingly, the transition metal oxide nano particles are filled in the sacrifice layer 100, namely, between the colloidal particles 110. In detail, the butanol solution having the titanium oxide nano particles (i.e., transition metal oxide nano particles) dispersed therein is filled in pores between the colloidal particles 110, and thereafter the titanium oxide nano particles are effectively infiltrated into the narrow pores between the colloidal particles 110 by a capillary attraction (i.e. using a capillary phenomenon), with the butanol being evaporated. Here, since each surface of the transition metal oxide nano particles is coated with a organic material (e.g., fluoric polymer), the transition metal oxide nano particles may have an excellent dispersion force within the sacrifice layer 100 consisting of an alcohol-based organic solvent. Accordingly, the transition metal oxide nano particles are uniformly dispersed between the colloidal particles 110, thereby overall implementing an inverse opal structure.

Hereinafter, an exemplary method for fabricating such photoelectrode material (comprising a method for fabricating the organic surface-treated transition metal oxide nano particles) having used in the above description will be described. The following method is given as an illustration, and thus the method is not limited thereto.

First, 0.1M to 0.4M acetylacetone is poured in 1-butanol. In detail, 48.33 g of 1-butanol is filled in a round bottom flask, and then 24.03 g of acetylacetone is further added therein. Afterwards, while the mixture is agitated, 0.1M titanium n-butoxide is added thereto to react therewith. In detail, while the mixture is agitated, 40.84 g of titanium n-butoxide is injected into the mixture by using a disposable needle.

Such mixture in the reactor is agitated for 15 minutes.

Afterwards, a mixture consisting of 21.6 g of deionized water and 8.265 g of p-toluene sulphonic acid (approximately 0.002M) is introduced in the reactor, to be agitated and dispersed.

The reactor is continuously stirred at 60° C. for 24 hours.

200 mL of the stirred solution is added to 2 L of toluene, thereby producing yellow sediments. Such yellow sediments are collected and the solvent is removed therefrom by centrifuge, to thereafter remove the residual solvent by a vacuum drying. Such processes are repeated plural times (for example, three times), so as to acquire organic surface-treated titanium oxide nano particles.

Here, during the fabricating processes, upon the synthesis of the organic surface-treated titanium oxides, size, crystallinity and dispersion of titanium oxide may be adjusted according to a mole ratio of titanium n-butoxide and acetylacetone. The size of the generated titanium oxide nano particles is apt to decrease when the ratio of [moles of acetylacetone]/[moles of titanium n-butoxide] increases.

FIG. 4 shows an organic surface-treated titanium oxide particle fabricated according to an exemplary embodiment. As shown, an spacing between lattices is 3.55 Å, and thusly the particle is constructed in an anatase crystal structure.

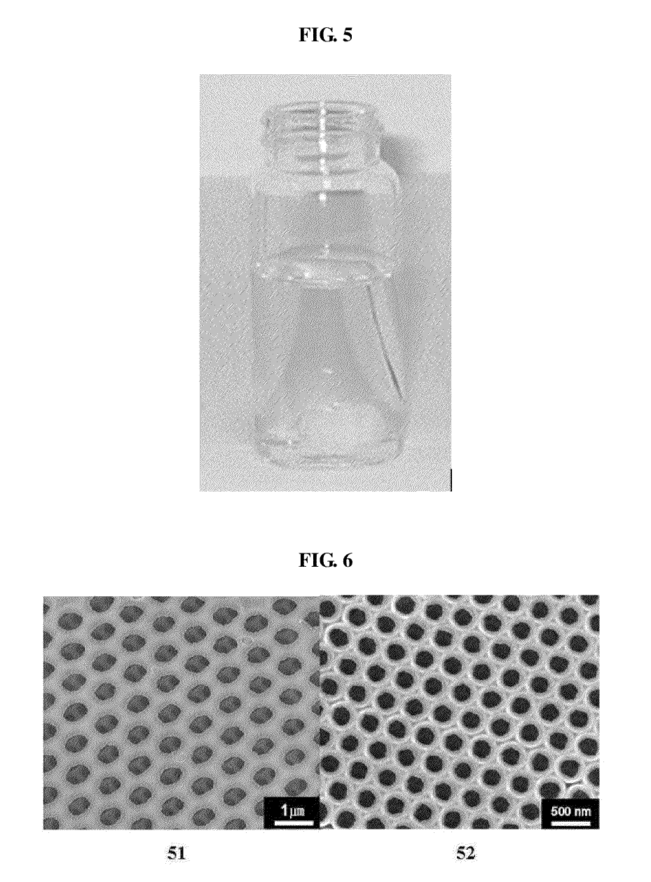

FIG. 5 shows a container with an n-butanol solution containing an organic surface-treated titanium oxide particles fabricated according to an exemplary embodiment.

According to an exemplary embodiment, the transition metal oxide nano particles has an average diameter in the range of 1 nm to 100 nm. While an exemplary embodiment used titanium dioxide nano particles as the transition metal oxide nano particles, it is not limited thereto, and one of zinc oxide (ZnO) nano particles or tin-dioxide (SnO₂) nano particles, or complex thereof may be used. In addition, other types of transition metal oxide nano particles may be applicable. According to an exemplary embodiment, the titanium dioxide nano particles having an anatase crystallinity with an electron transport capability may be selected for use.

As shown in FIG. 3E, after the transition metal oxide nano particles are filled between the colloidal particles (e.g., polystyrene colloidal particles), a thermal treatment is performed for the resultant to remove the colloidal particles. The thermal treatment may fire the transition metal oxide nano particles as well as remove the colloidal particles. Here, although not shown, in order to improve the adhesiveness between the transition metal oxide nano particles and the blocking layer 20 and reduce cracks on the substrate, the sacrifice layer 100 may be pressed from its upper side by a substrate coated with a fluoric polymer. The thermal treatment is performed under the conditions that the resultant is heated from room temperature up to about 400° C. to 450° C. by 0.2° C. per minute under an air atmosphere, and then maintained at a constant temperature of about 400° C. to 450° C. for 2 hours. The thusly-obtained resultant is then naturally cooled.

After removing the substrate coated with the fluoric polymer, the substrate-removed resultant is heated again up to 500° C. to 550° C. by 0.2° C. per minute. The heated resultant is then thermally treated at about 500° C. to 550° C. for 2 hours to be cooled in air, thereby forming photoelectrode 30 with a thickness of 10 μm to 30 μm.

The steps of forming the sacrifice layer, filling the transition metal oxide nano particles and removing the sacrifice layer may be repeated at least one time. Also, the aforementioned series of processes are repeatedly performed plural times so as to complete porous photoelectrode 30 with a multi-layered structure. FIG. 6 shows a surface of the photoelectrode 30 fabricated according to an exemplary embodiment. In detail, a left 51 of FIG. 6 shows a surface of the titanium oxide photoelectrode in an inverse opal structure prepared by using 1 μm of polymer particles and the organic surface-treated titanium oxide nano particles, and a right 52 of FIG. 6 shows a surface of the titanium oxide photoelectrode in an inverse opal structure prepared by using 500 nm of polymer particles and the organic surface-treated titanium oxide nano particles.

Such fabricated photoelectrode 30 is prepared in the inverse opal structure having a porosity, and accordingly a three-dimensional photonic crystal may be constructed, by which a light amplification effect may be expected. In detail, an effective electron transport path is formed by the porous inverse opal structure in a constant order, thus to enhance a photonic conversion efficiency of the dye-sensitized solar cell 1. Also, the ordered bulk-pores in the inverse opal structure may provide a path efficient for the infiltration of polymer with a high viscosity or solid electrolyte, thereby improving a long-term stability of the dye-sensitized solar cell 1.

Upon fabricating the photoelectrode 30 of the photonic crystalline, various sizes of particles may be used to adjust thicknesses and sizes of pores. As well as organic particles, such as polystyrene (PS), polymethylmethacrylate (PMMA) or the like, inorganic particles, such as silica or the like, may also be used as the micro particles.

Through such processes, the photoelectrode 30 with the inverse opal structure may be fabricated.

Hereinafter, a description will be given of an exemplary method for fabricating a dye-sensitized solar cell using the thusly fabricated photoelectrodes, and the performance of the fabricated dye-sensitized solar cell.

The photoelectrode in the inverse opal structure having fabricated according to the above embodiment was adsorbed on the dye molecules 40 within a dye solution for 24 hours. In this example, a solution of N719 (solaronix)/ethyl alcohol in a concentration of 0.5 mM was used. In order to prepare the platinum layer 60 of the counter electrode 50, a solution of hexachloro platinum acid (H₂PtCl₆.H₂O, Aldrich)/isopropyl alcohol solution in a concentration of 10 mM was spin-coated (1^{st}; 500 rpm, 5 sec; 2^{nd}; 1000 rpm, 5 sec; 3^{rd}; 2000 rpm, 40 sec) on the transparent conductive substrate 10 and heated up from room temperature up to 400° C. by 4° C. per minute at an air atmosphere, thereafter to be thermally treated at 400° C. for 15 minutes, thereby being naturally cooled.

As an electrolyte solution, a liquid electrolyte having iodine-based oxidation-reduction pair was used, namely, 0.6M 1,2-dimetyl-3-hexyl-imidazolium iodide, 0.2M lithium iodide and 0.1M iodine (I2) were dissolved in a solution containing acetonitrile and 3-methoxypropionitrile mixed by 1:1 for use. In order to raise an open circuit voltage, 4-tertiary-butyl pyridine was added as an additive in a concentration of 0.5M. In order to prevent a leakage of the electrolyte solution, surlyn with a thickness of 60 μm was used as a thermoplastic polymer.

For such fabricated dye-sensitized solar cell, values of current density (J_{SC}), voltage (V_{OC}), charging coefficient (FF) and energy conversion efficiency (Eff.) were measured under a condition of AM1.5 and 100 mW/cm². The measured results were represented in Table 1.

TABLE 1

| Diameter of | | | Jsc | | Eff. |
|---|---|---|---|---|---|
| pore | Thickness of electrode | Voc (V) | (mA/cm²) | FF | (%) |
| 1 μm | 12 μm | 0.726 | 6.42 | 74.4 | 3.47 |

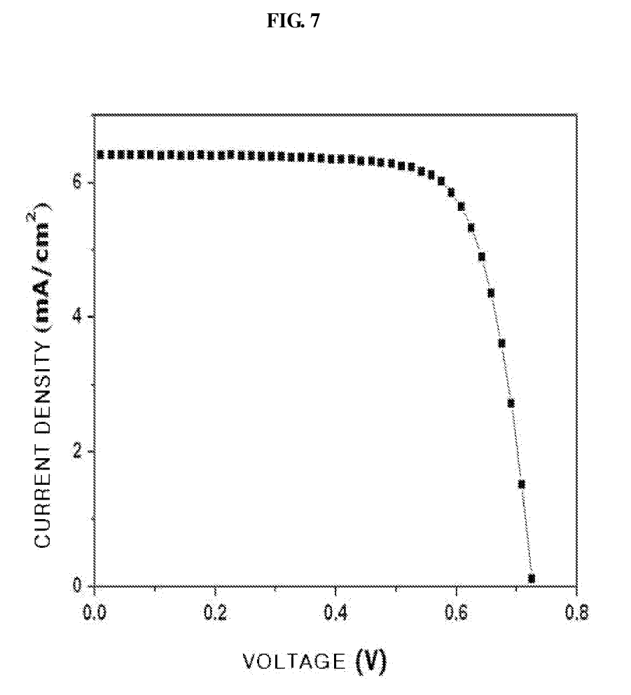

FIG. 7 shows photonic current-voltage characteristics of the dye-sensitized solar cell in the inverse opal structure obtained under the condition of AM1.5 and 100 mW/cm².

As shown in Table 1, a dye-sensitized solar cell in an inverse opal structure fabricated according to an exemplary embodiment may obtain a maximum photonic conversion efficiency of 3.47%. That is, the photonic conversion efficiency may be improved by about 600% compared to a maximum efficiency (0.6%) of a dye-sensitized solar cell in an inverse opal structure fabricated according to an existing sol-gel method (C. Huisman, J. Schonman, A. Goossens, Sol. Energy Mater. Sol. Cells, 85, 2005, 115-24).

A dye-sensitized solar cell according to an exemplary embodiment may have one or more of the following improvements and/or effects using a transition metal oxide (for example, titanium oxide) electrode with an inverse opal structure fabricated using organic surface-treated titanium oxide nano particles and a three-dimensional colloidal template (i.e. a sacrifice layer).

According to an aspect, the use of the organic surface-treated titanium oxide having high dispersion may allow the fabrication of the dye-sensitized solar cell with various structures based upon a self-assembled structure of colloidal particles.

According to another aspect, the organic surface-treated titanium oxide particles may have an anatase crystallinity with an excellent electron transport ability, thus defining an effective electron transport path and improving a photonic conversion efficiency of the dye-sensitized solar cell.

According to still another aspect, instead of using a titanium precursor typically used in fabrication of titanium oxide electrodes with an inverse opal structure, titanium oxide nano particles (1˜100 nm, for example, 5˜50 nm) may be used, thus enhancing the amount of adsorbed dyes and increasing the current density.

According to still another aspect, the electrode with the inverse opal structure may create a three-dimensional photonic crystal, thus achieving a photonic amplification effect and resulting in improvement of the photonic conversion efficiency.

According to still another aspect, ordered bulk-pores of the inverse opal electrode may provide a path efficient for an infiltration of polymer with a high viscosity or solid electrolyte, thereby enhancing a long-term stability of the dye-sensitized solar cell.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A dye-sensitized solar cell comprising:
a transparent conductive substrate;
a photoelectrode formed with an inverse opal structure on the transparent conductive substrate and comprising organic surface-treated transition metal oxide nano particles;
dye molecules adsorbed on the photoelectrode;
a counter electrode disposed to face the transparent conductive substrate; and
an electrolyte filled between the transparent conductive substrate and the counter electrode.

2. The solar cell of claim 1, wherein each surface of the transition metal oxide nano particles is coated with a hydrophobic organic material.

3. The solar cell of claim 2, wherein the hydrophobic organic material is ketone or alcohol-based compound.

4. The solar cell of claim 2, wherein a coating layer comprising the hydrophobic organic material has an average thickness of 0.1 nm to 20 nm.

5. The solar cell of claim 1, wherein the transition metal oxide nano particles include at least one of titanium dioxide nano particles, zinc oxide nano particles, tin-dioxide nano particles, and one or more of the titanium dioxide nano particles have an anatase crystallinity.

6. The solar cell of claim 1, wherein the transition metal oxide nano particles have an average diameter of 1 nm to 100 nm.

7. The solar cell of claim 1, wherein the photoelectrode is porous and has two or three dimensional ordered crystal structure.

8. The solar cell of claim 1, wherein the photoelectrode has a plurality of pores, the pores having an average diameter of 100 nm to 10 μm.

9. The solar cell of claim 1, further comprising a blocking layer disposed between the transparent conductive substrate and the photoelectrode.

10. A method for fabricating a dye-sensitized solar cell, the method comprising:
forming a sacrifice layer comprising colloidal particles on a transparent conductive substrate;
supplying a photoelectrode material comprising transition metal oxide nano particles onto the sacrifice layer, thereby filling the transition metal oxide nano particles between the colloidal particles;
removing the sacrifice layer by thermal treatment to prepare a photoelectrode having an inverse opal structure; and
adsorbing dye molecules onto the photoelectrode.

11. The method of claim 10, wherein the colloidal particles have an average diameter of 100 nm to 10 μm.

12. The method of claim 10, wherein the colloidal particles are either organic polymer particles or inorganic particles.

13. The method of claim 12, wherein the organic polymer particles contain at least one of polystyrene (PS) and polymethylmethacrylate (PMMA).

14. The method of claim 12, wherein the inorganic particles contain silica.

15. The method of claim 10, wherein the photoelectrode material is prepared by dispersing the transition metal oxide nano particles in water or alcohol, and the transition metal oxide nano particles are uniformly filled between the colloidal particles by capillary phenomenon with the water or the alcohol being evaporated.

16. The method of claim 10, wherein each surface of the transition metal oxide nano particles is coated with a hydrophobic organic material.

17. The method of claim 10, wherein the thermal treatment is performed at least one time at 400° C. to 550° C. for 10 minutes to 2 hours.

18. The method of claim 10, further comprising pressing the sacrifice layer by using a substrate coated with a fluoric polymer after the transition metal oxide nano particles are filled between the colloidal particles.

19. The method of claim 10, wherein a series of steps comprising the step of forming the sacrifice layer, the step of filling the transition metal oxide nano particles between the colloidal particles, and the step of removing the sacrifice layer by thermal treatment are repeated at least one time or more.

20. The method of claim 10, further comprising forming a blocking layer between the transparent conductive substrate and the photoelectrode before forming the sacrifice layer.
